(19) United States
(12) Patent Application Publication
(10) Pub. No.: US 2021/0028084 A1
(43) Pub. Date: Jan. 28, 2021

(54) VARIABLE-THICKNESS INTEGRATED HEAT SPREADER (IHS)

(71) Applicant: Intel Corporation, Santa Clara, CA (US)

(72) Inventors: Sergio Antonio Chan Arguedas, Chandler, AZ (US); Edvin Cetegen, Chandler, AZ (US); Baris Bicen, Chandler, AZ (US); Aravindha R. Antoniswamy, Phoenix, AZ (US)

(73) Assignee: Intel Corporation, Santa Clara, CA (US)

(21) Appl. No.: 16/518,643

(22) Filed: Jul. 22, 2019

(51) Int. Cl. H01L 23/367; H01L 23/00

(52) U.S. Cl. CPC H01L 23/3675; H01L 2924/3512; H01L 24/83; H01L 2224/32245; H01L 24/33; H01L 24/16; H01L 24/73; H01L 2224/32225; H01L 2224/16225; H01L 2224/33181; H01L 2224/73204; H01L 2224/73253; H01L 2924/20642; H01L 2924/20643; H01L 2924/20644; H01L 2224/32059; H01L 24/32

(57) ABSTRACT

Embodiments may relate to a microelectronic package that includes a die, a thermal interface material (TIM) coupled with the die, and an integrated heat spreader (IHS) coupled with the TIM. The IHS may include a feature with a non-uniform cross-sectional profile that includes a thin point and a thick point as measured in a direction perpendicular to a face of the die to which the TIM is coupled. Other embodiments may be described or claimed.

### BACKGROUND

Microelectronic packages that utilize a thermal interface material (TIM) such as a solder-based TIM (STIM) or a polymer-based TIM (PTIM) may require a thicker TIM layer to control package stress and void solder cracking or first layer interconnect (FLI) joint breakage. Typical TIM thicknesses may be in the range of between approximately 9 mils and approximately 16 mils.

### BRIEF DESCRIPTION OF THE DRAWINGS

FIG. 1 depicts a simplified example cross-sectional view of a microelectronic package with a variable-thickness integrated heat spreader (IHS), in accordance with various embodiments.

FIG. 2 depicts an alternative simplified example cross-sectional view of a microelectronic package with a variable-thickness IHS, in accordance with various embodiments.

FIG. 3 depicts an alternative simplified example cross-sectional view of a microelectronic package with a variable-thickness IHS, in accordance with various embodiments.

FIG. 4 depicts an example simplified top-down view of a microelectronic package with a variable-thickness IHS, in accordance with various embodiments.

FIG. 5 depicts an example technique for manufacturing a microelectronic package with a variable-thickness IHS, in accordance with various embodiments.

FIG. 6 is a top view of a wafer and dies that may include a microelectronic package with a variable-thickness IHS, in accordance with various embodiments.

FIG. 7 is a side, cross-sectional view of an integrated circuit (IC) device assembly that may include a microelectronic package with a variable-thickness IHS, in accordance with various embodiments.

FIG. 8 is a block diagram of an example electrical device that may include a microelectronic package with a variable-thickness IHS, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature [[formed/deposited/disposed/etc.]] on a second feature,” may mean that the first feature is formed/deposited/disposed/etc. over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise. Additionally, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined, e.g., using scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

As noted above, microelectronic packages that utilize a TIM may require a relative thick TIM layer to control package stress and void solder cracking or FLI joint breakage. Typical TIM thicknesses may be in the range of approximately 9 to approximately 16 mils. However, a thicker TIM may negatively impact the thermal efficiency of the TIM. In other words, as the TIM gets thicker, the TIM may be less capable of transferring thermal energy from a die to an IHS. A thinner layer of TIM may be desirable to maximize thermal performance of the microelectronic package; however, the thinner layer of TIM may negatively impact mechanical performance of the microelectronic package.

Generally, embodiments herein may relate to a microelectronic package with a variable TIM and variable IHS thickness. Specifically, the TIM may be thicker at higher-stress areas of the die or microelectronic package, and the TIM may be thinner at lower-stress areas of the die or microelectronic package. As an example, TIM failure may generally occur at the edge or periphery of the die, especially when the microelectronic package is used in a server and includes a larger type of die. In this embodiment, the TIM may be thicker (and, conversely, the IHS may be thinner) at the edge of the die. The TIM may be thinner (and, conversely, the IHS may be thicker) near the center of the die.

A variable-thickness IHS may enable a thinner TIM on a significant portion of the die area (e.g., 50% or more of the die area) for better heat extraction from the die and increased thermal performance of the microelectronic package. However, the IHS may similarly enable a thicker TIM (and thinner IHS) at higher-stress areas of the microelectronic package which may extend the mechanical life of the package.

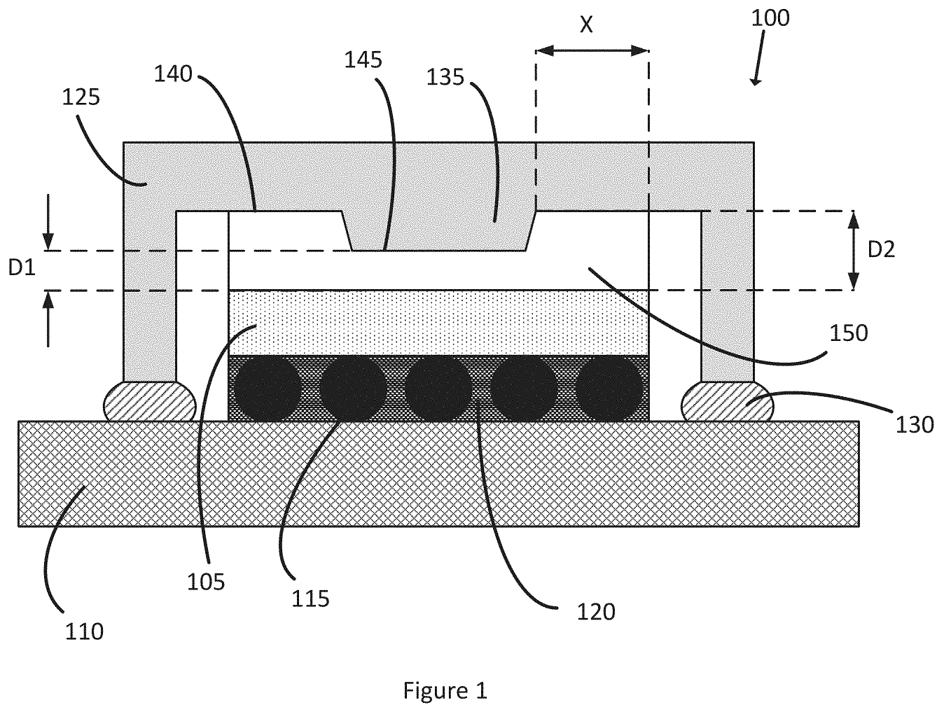

FIG. 1 depicts an example microelectronic package 100 with a variable-thickness IHS, and accordingly a variable-thickness TIM, in accordance with various embodiments. Generally, the package 100 may include a die 105 coupled with a package substrate 110. The die 105 may be or include, for example, a processor such as a central processing unit (CPU), graphics processing unit (GPU), a core of a distributed processor, or some other type of processor. Alternatively, the die 105 may be include a memory such as a double data rate (DDR) memory, a nonvolatile memory (NVM), a volatile memory, a read-only memory (ROM), or some other type of memory or die. In some embodiments the die 105 may be or include a radio frequency (RF) chip or RF circuitry that is configured to generate, process, transmit, or receive a wireless signal such as a third generation (3G), a fourth generation (4G), a fifth generation (5G), a Wi-Fi, or some other type of wireless signal. In some embodiments the die 105 may include one or more passive components such as capacitors, resistors, etc. The various active or passive components may be positioned within, partially within, or on the surface of the die 105.

The package substrate 110 may be, for example, considered to be a cored or coreless substrate. The package substrate 110 may include one or more layers of a dielectric material which may be organic or inorganic. The package substrate 110 may further include one or more conductive elements such as vias, pads, traces, microstrips, striplines, etc. The conductive elements may be internal to, or on the surface of, the package substrate. Generally, the conductive elements may allow for the routing of signals through the package substrate 110, or between elements that are coupled to the package substrate 110. In some embodiments the package substrate 110 may be, for example, a printed circuit board (PCB), an interposer, a motherboard, or some other type of substrate. It will be understood that although the package substrate 110 is discussed herein as an element of the microelectronic package 100, in other embodiments the package substrate 110 may be considered to be an element separate from the microelectronic package 100 to which the microelectronic package 100 is coupled.

Generally, the die 105 may be coupled with the package substrate 110 by one or more interconnects 115. The interconnects 115 may be, for example, solder bumps that are formed of a material such as tin, silver, copper, etc. If solder bumps are used for the interconnects 115, then the solder bumps may be elements of a ball grid array (BGA) as shown in FIG. 1. In other embodiments, the interconnects 115 may be pins of a pin grid array (PGA), elements of a land grid array (LGA), or some other type of interconnect. Generally, the interconnects 115 may physically or communicatively couple the die 105 with the package substrate 110. For example, one or more of the interconnects 115 may physically couple with, and allow electrical signals to pass between, pads of the die 105 and pads of the package substrate 110 (not shown for the sake of elimination of clutter of FIG. 1). In other embodiments, the interconnects 115 may physically couple the die 105 and the package substrate 110, but the interconnects 115 may not communicatively couple the die 105 and the package substrate 110.

The microelectronic package may further include an underfill material 120. The underfill material 120 may at least partially surround the interconnects 115, and may at least partially fill the space between the die 105 and the package substrate 110. Generally, the underfill material 120 may lend further structural stability to the microelectronic package 100 and strengthen the connection between the die 105 and the package substrate 110. The underfill material 120 may be formed of a polymer material such as epoxy or some other material.

The microelectronic package 100 may further include a TIM 150. In some embodiments the TIM may be a STIM which may be formed of or include, for example, indium or some other solderable material. In other embodiments the TIM may be a PTIM which may be formed of or include, for example, epoxy or silicone with thermally conductive fillers such as boron nitride, alumina, aluminum, zinc oxide, silver, etc. Generally, the TIM 150 may be considered to be a thermally conductive material. The TIM 150 may couple with an IHS 125. The IHS 125 may be formed of a thermally conductive material such as copper or some other material. The IHS 125 may couple with a thermal solution such as a vapor chamber, a water-cooled cooling apparatus, fins, or some other type of thermal solution. The thermal solution is not depicted in FIG. 1 for the sake of reduction of clutter of the Figure. In operation, the TIM 150 may serve to draw thermal energy from the die 105. The thermal energy may be generated through operation of the die 105 and, if the die 105 is a high-performance die, then the die 105 may generate a significant amount of thermal energy. The thermal energy may travel from the TIM 150 to the IHS 125 where the thermal energy may then be dispersed through the IHS 125. The IHS 125 may transfer the thermal energy to the thermal solution where the thermal energy may be dispersed away from the microelectronic package 100.

In embodiments, the IHS 125 may be coupled with the package substrate 110. Specifically, the IHS may be coupled with the package substrate 110 by a sealant 130 as shown in FIG. 1. The sealant 130 may be conductive or non-conductive in nature. That is, in some embodiments the sealant 130 may couple with conductive elements of the IHS 125 and the package substrate 110 (e.g., pads) and route electrical signals between the two elements in addition to physically coupling the package substrate 110 and the IHS 125. In other embodiments, the sealant 130 may not route electrical signals.

In some embodiments the sealant 130 may be replaced by, or include, one or more interconnects with an underfill material. In some embodiments the IHS 125 may not be a unitary element but, rather, the IHS 125 may be a generally lateral plate that is coupled with the TIM 150, and the IHS 125 may further include one or more spacers or stiffeners that are coupled with, and positioned between, the plate and the package substrate 110. In various embodiments, the spacers or stiffeners may be coupled with the plate of the IHS by a sealant such as sealant 130, one or more interconnects, or some other type of connection.

In some embodiments the IHS 125 may have a variable width. Specifically, as shown in FIG. 1, the IHS 125 may include a feature 135. The feature 135 may be referred to as a “pedestal.” Specifically, the feature 135 may protrude from the face 140 of the IHS 125 to which the TIM 150 is coupled. As can be seen, the TIM 150 may therefore be coupled with the face 140 of the IHS 125 and the face 145 of the feature 135. Although the IHS 125 and the feature 135 are depicted as a unitary element in FIG. 1, it will be understood that in some embodiments the feature 135 and the remainder of the IHS 125 may be formed of different elements or constructed separately, and subsequently coupled with one another. In other embodiments the feature 135 and the IHS 125 may be formed jointly, for example through stamping, die casting, or some other technique. Additionally, although the face 140 of the IHS 125 and the face 145 of the feature 135 are discussed as separate elements herein, it will be understood that this separate is a logical separation for the sake of discussion and generally the faces 140 and 145 may be jointly considered to be the “face of the IHS” in some embodiments.

As can be seen in FIG. 1, the TIM 150 may have two different heights as measured in a direction perpendicular to the face of the die 105 to which the TIM 150 is attached. For example, the TIM 150 may be thinner adjacent to the feature 135, and thicker at an area that is not adjacent to the feature 135. In some embodiments, the thinner portion of the TIM 150 that is adjacent to the feature 135 may have a thickness D1 of less than approximately 9 mils. In some embodiments, the thickness D1 may be less than approximately 8 mils. By contrast, the thicker portion of the TIM 150 that is not adjacent to the feature 135 may have a thickness D2 of between approximately 9 mils and approximately 16 mils. However, it will be understood that in other embodiments D1 or D2 may be greater or smaller than stated above based on, for example, factors such as the type of TIM material used, the type of die used, the type of IHS used, the specific use case to which the microelectronic package 100 will be put, specific hot spots of the die 105, specific stress characteristics of the IHS 125, etc.

Additionally, as can be seen in FIG. 1, the footprint of the feature 135 may be smaller than the footprint of the die 105. As used herein, the term “footprint” of an element may refer to the lateral size of the element as oriented in FIG. 1. Generally, the edge of the feature 135 may be a distance X from the edge of the die 105. In some embodiments X may be between approximately 20% and approximately 30% of the total lateral size of the die 105. More specifically, in some embodiments X may be approximately 25% of the total lateral size of the die 105. However, similarly to D1 or D2, X may vary in other embodiments based on factors such as those discussed above with respect to D1 and D2.

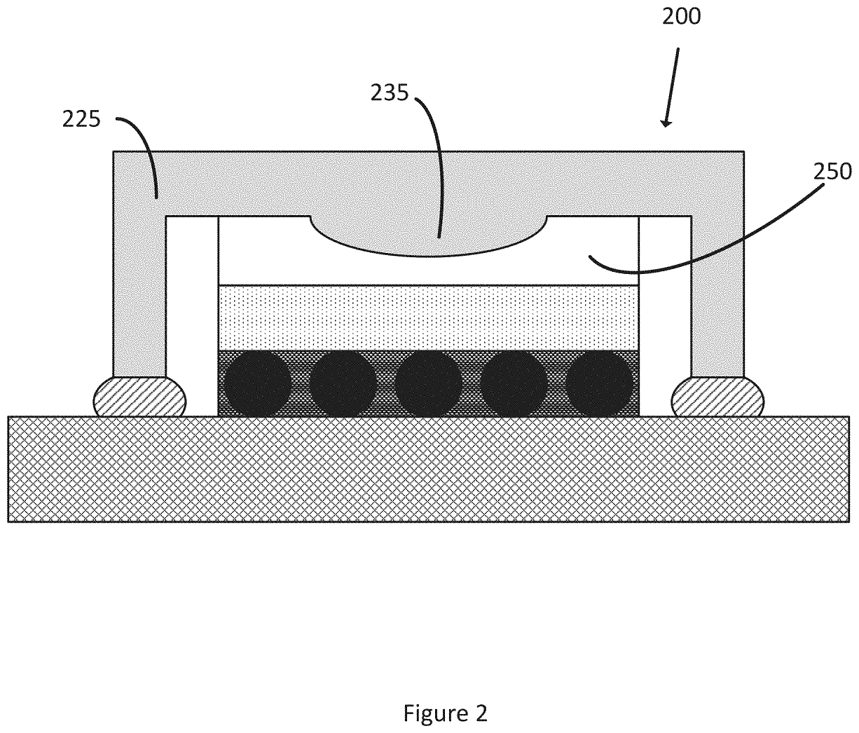

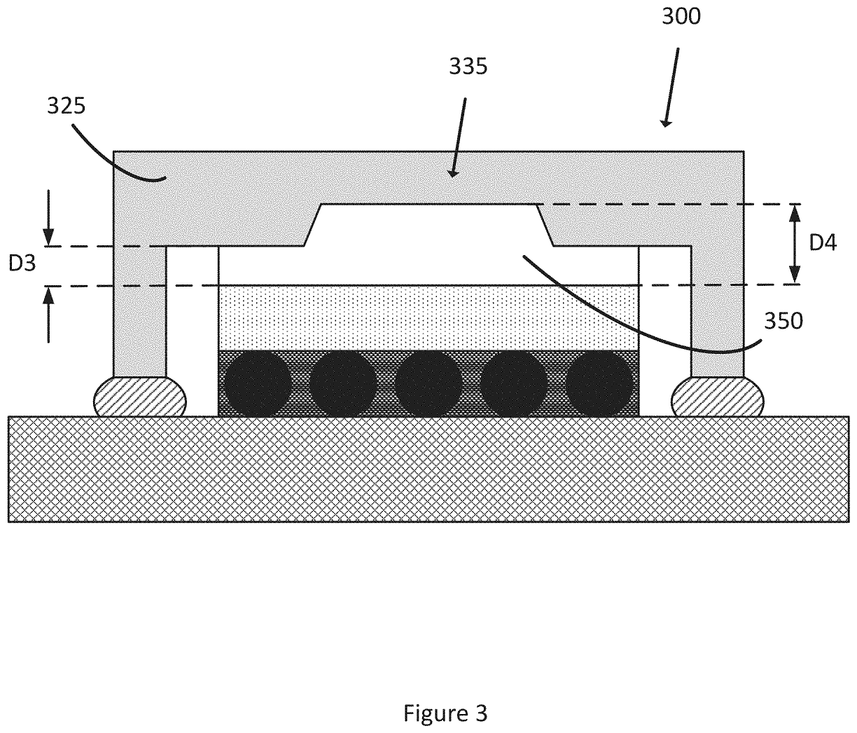

FIG. 2 depicts an alternative simplified example cross-sectional view of a microelectronic package 200 with a variable-thickness IHS 225, in accordance with various embodiments. It will be understood that each and every element of the embodiments of FIGS. 2 or 3 may not be specifically enumerated or discussed for the sake of lack of redundancy. However, elements of those Figures that appear identical to elements of FIG. 1 (e.g., the die, package substrate, interconnects, underfill, sealant, etc.) may share one or more characteristics with those elements of FIG. 1.

Generally, the microelectronic package 200 may include a TIM 250, which may be similar to, and share one or more characteristics with, TIM 150. The IHS 225 may include a feature 235 which may be similar to, and share one or more characteristics with, feature 135. However, as can be seen in FIG. 2, the feature 235 may not be linear but rather may have a generally curved non-uniform profile. The curved profile may be desirable for a variety of factors such as if a more gradual change to the TIM 250 is desired, if it is easier to manufacture, etc.

In some embodiments, higher-stress portions of the die or microelectronic package may be located near a central portion of the microelectronic package. In these embodiments, it may be desirable for the IHS to be thinner near the central portion of the microelectronic package, and thicker near the periphery of the microelectronic package. Correspondingly, the TIM may be thicker near the central portion of the microelectronic package, and thinner near the periphery of the microelectronic package. Such an embodiment may be seen in FIG. 3.

FIG. 3 depicts an alternative simplified example cross-sectional view of a microelectronic package 300 with a variable-thickness IHS 325, in accordance with various embodiments. Generally, the IHS 325 may be similar to, and share one or more characteristics with, IHS 125. The microelectronic package 300 may further include a TIM 350 which may be similar to, and share one or more characteristics with, TIM 150.

The IHS 325 may further include a feature 335. In this embodiment, rather than a pedestal-type feature, the feature 335 may be a cavity in the IHS 325. Similarly to feature 135, in some embodiments the feature 335 may be stamped into the IHS 325, etched into the IHS 325, etc. Additionally or alternatively, the IHS 325 may include two or more portions. In this embodiment, one portion of the IHS 325 may be manufactured separately from another portion of the IHS 325, and then the various portions may be coupled together to form the IHS 325 with the feature 335.

As can be seen, similarly to FIG. 1, the TIM 350 may have two portions with different thicknesses. The thinner portion of the TIM 350, which may correspond to a portion of the TIM 350 that is not adjacent to the feature 335 may have a thickness D3, which may be generally similar to D1. The thicker portion of the TIM 350, which may correspond to a portion of the TIM 350 that is adjacent to the feature 335, may have a thickness D4, which may be generally similar to D4. Specifically, in some embodiments D3 may be less than approximately 9 mils, and in some embodiments D3 may be less than approximately 8 mils. D4 may be between approximately 9 mils and approximately 16 mils. However, D3 and D4 may be different in different embodiments based on one or more factors such as those discussed above.

Generally, it will be understood that the above-described embodiments of FIGS. 1-3 are intended as simplified example embodiments. Other embodiments may include more or fewer features than are depicted in FIGS. 1-3. For example, various additional layers, interconnects, active or passive components, etc. may be present in various of the microelectronic packages 100-300. In some embodiments, the various microelectronic packages may include a plurality of dies (e.g., by implemented as multi-chip packages (MCPs)) In some embodiments, more or fewer interconnects may be included than are shown in the various Figures. Generally, unless discussed above, the relative sizes or locations of features are depicted herein for the sake of discussion and illustration of concepts related to embodiments herein. However, the relative sizes or locations of various features may be different in other embodiments, and the specific depicted relative sizes of various elements may not be determinative of their relative sizes in real-world embodiments.

It will also be understood that the above-depicted features 135/235/335 are intended as examples of various embodiments. Other embodiments may have different non-uniform profiles. For example, the various angles of the plurality of generally-linear portions of the features 135/335 in FIG. 1 or 3 may be different. In some embodiments the linear portions of the features 135/335 may be non-parallel and non-perpendicular as depicted in the Figures, whereas in other embodiments the linear portions of the features 135/335 may be perpendicular, or may include portions that are generally parallel with one another. In some embodiments, the features may have other non-uniform cross-sectional profiles such as being wavy, saw-toothed, squared, having a cavity with a rounded profile such as in FIG. 2, etc. In some embodiments, the features may not be a single feature, but rather there may be a plurality of features which may be conjoined with, or separated from, one another. Other variations may be present in other embodiments.

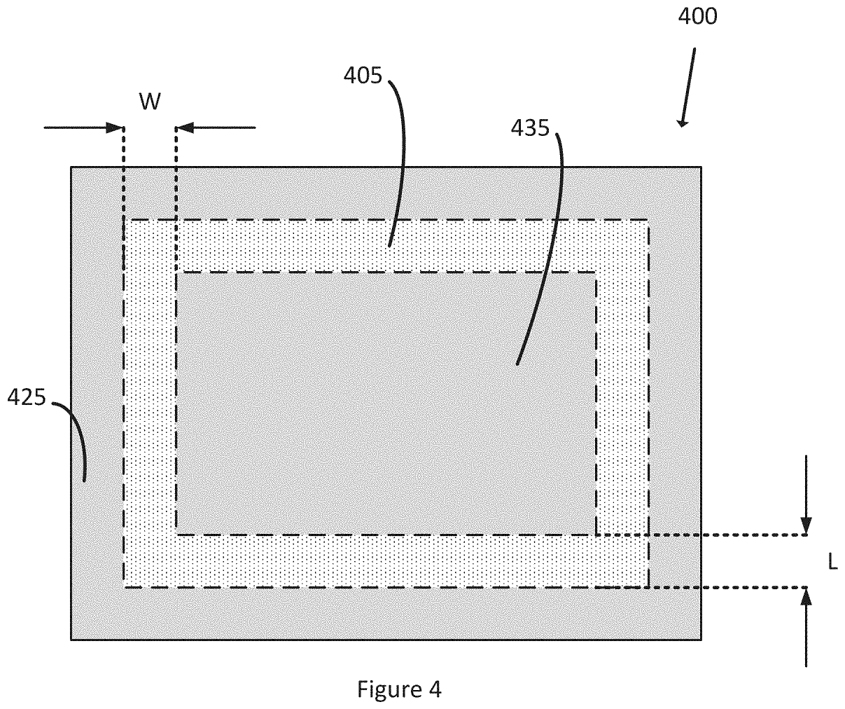

FIG. 4 depicts an example simplified top-down view of a microelectronic package 400 with a variable-thickness IHS, in accordance with various embodiments. Specifically, FIG. 4 depicts an example top-down view to show the relative footprints of a die and a feature of an IHS as described herein. The microelectronic package 400 may include a die 405, an IHS 425, and a feature 435 which may be respectively similar to, and share one or more characteristics with, die 105, IHS 125, and feature 135.

As can be seen, the die 405 may have a smaller footprint than the IHS 425, which may also be observed in FIG. 1 with respect to die 105 and IHS 125. The feature 435 may have a smaller footprint than the die 405, which may be likewise observed in FIG. 1 with respect to die 405 and IHS 425. Generally, the feature 435 may have a smaller footprint than the die 405 with respect to both a length L and a width W of the die. In some embodiments, one or both of the length L and width W may be equal to the distance X as described above. In some embodiments, the length L and the width W may be equal to one another, while in other embodiments the length L and the width W may be different from one another. In some embodiments, the length L or width W may be equal on both sides of the die 405, while in other embodiments the footprint different on opposite sides of the die 405 may be different from one another.

It will be understood that FIG. 4 is intended as an example embodiment, and in some embodiments one or more of the depicted elements of the microelectronic package 400 may have a different cross-section than is depicted. For example, one or more of the IHS 425, die 405, or feature 435 may not have the depicted generally rectangular cross-section, but rather may have a cross-section with rounded corners, a circular cross-section, a square cross-section, a non-uniform cross-section, etc. It will also be understood that although FIG. 4 is discussed with respect to elements of FIG. 1, the concepts of FIG. 4 may likewise be applicable to elements of FIG. 2, FIG. 3, or some other embodiment herein.

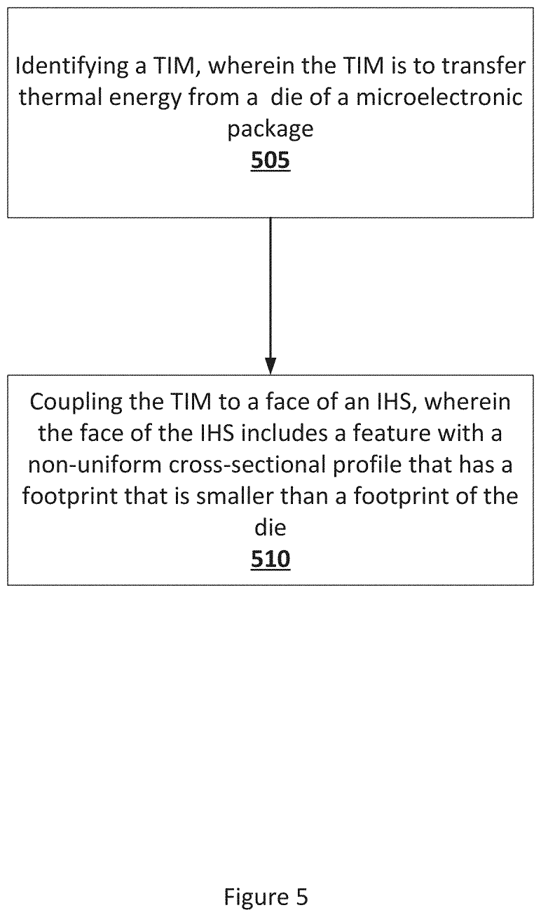

FIG. 5 depicts an example technique for manufacturing a microelectronic package with a variable-thickness IHS, in accordance with various embodiments. Generally, it will be understood that FIG. 5 is intended as a simplified example technique, and other techniques may include more or fewer elements than depicted in FIG. 5. Also, it will be understood that although FIG. 5 is discussed with respect to elements of FIG. 1, the technique of FIG. 5 may be applicable, in whole or in part, with or without modification, to elements of other embodiments of the present disclosure.

The technique may include identifying, at 505, a TIM. The TIM may be similar to, for example, TIM 150 of FIG. 1. Generally, the TIM may be configured to transfer thermal energy from a die such as die 105 of a microelectronic package such as microelectronic package 105 as described above.

The technique may further include coupling, at 510, the TIM to a face of an IHS such as face 140 of IHS 125. Coupling the TIM may include placing the TIM on a die, for example by placing a TIM preform on the die, or placing the TIM on the IHS by spraying or otherwise depositing the TIM on the face of the IHS. The IHS may include a feature such as feature 135 with a non-uniform cross-sectional profile. As can be seen in FIG. 1, coupling the TIM to the face of the IHS may include coupling the TIM to a face of the feature such as face 145. Further, as can be seen in FIG. 1, the feature may have a footprint that is smaller than a footprint of the die.

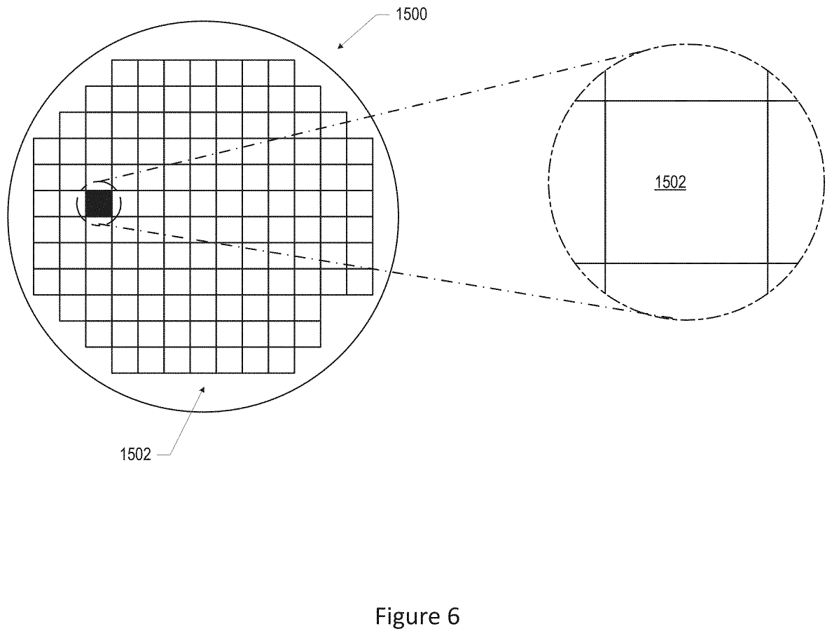

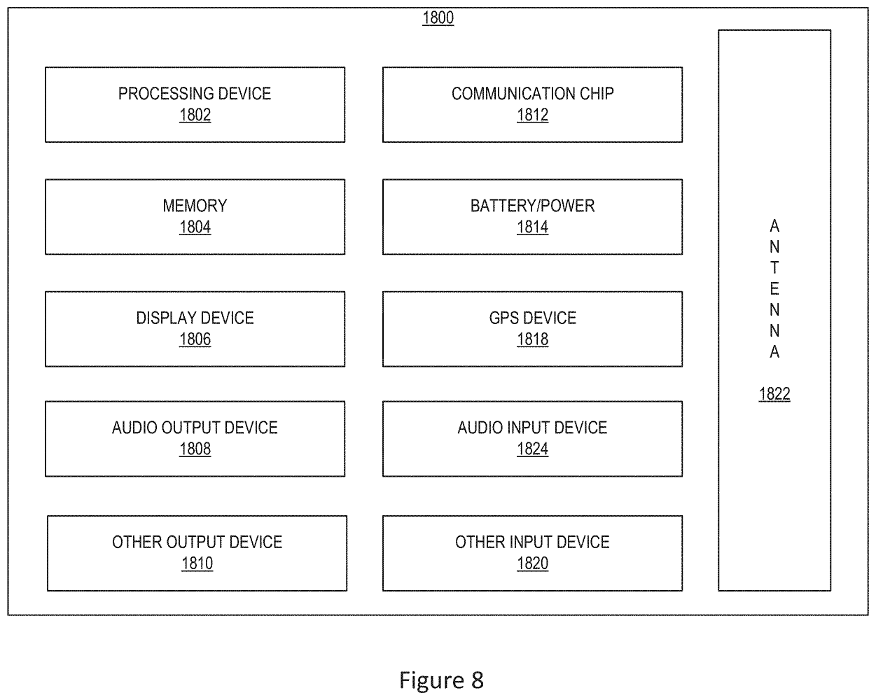

FIG. 6 is a top view of a wafer 1500 and dies 1502 that may be included in microelectronic package with a variable-thickness IHS in accordance with various embodiments. The wafer 1500 may be composed of semiconductor material and may include one or more dies 1502 having IC structures formed on a surface of the wafer 1500. Each of the dies 1502 may be a repeating unit of a semiconductor product that includes a suitable IC. After the fabrication of the semiconductor product is complete, the wafer 1500 may undergo a singulation process in which the dies 1502 are separated from one another to provide discrete “chips” of the semiconductor product. The die 1502 may include one or more transistors or supporting circuitry to route electrical signals to the transistors, or some other IC component. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 8) or other logic that is configured to store information in the memory devices or execute instructions stored in the memory array.

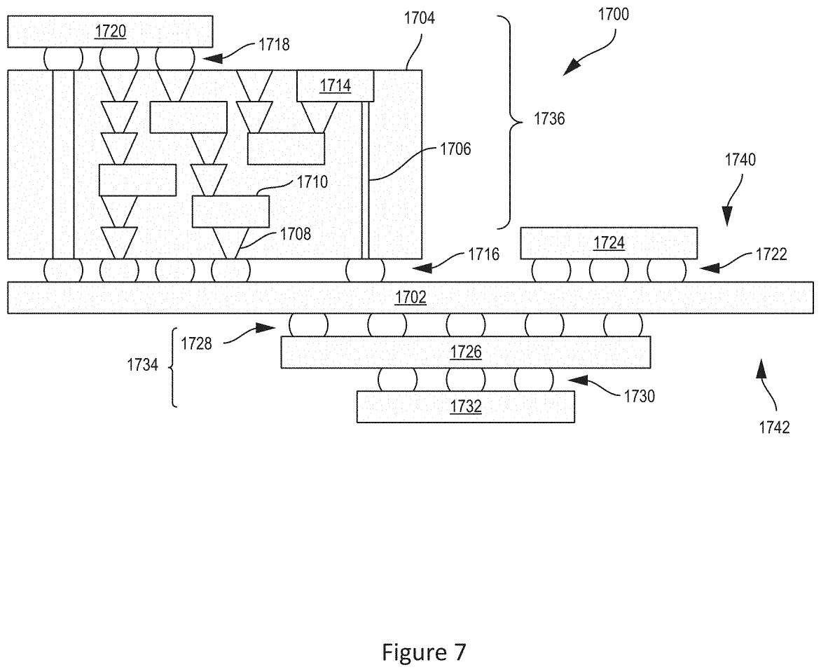

FIG. 7 is a side, cross-sectional view of an IC device assembly 1700 that may include one or more IC packages or other electronic components (e.g., a die) with a variable-thickness IHS, in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 7 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 7), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 7, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 6), an IC device, or any other suitable component. Generally, the package interposer 1704 may spread a connection to a wider pitch or reroute a connection to a different connection.

For example, the package interposer 1704 may couple the IC package 1720 (e.g., a die) to a set of BGA conductive contacts of the coupling components 1716 for coupling to the circuit board 1702. In the embodiment illustrated in FIG. 7, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 7 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 8 is a block diagram of an example electrical device 1800 that may include one or more microelectronic packages with a variable-thickness IHS, in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 8 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 8, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), CPUs, GPUs, cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., ROM), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

### Examples of Various Embodiments

Example 1 includes a microelectronic package comprising: a die; a TIM coupled with the die; and an IHS coupled with the TIM, wherein: the IHS has a feature with a non-uniform cross-sectional profile that includes a thin point and a thick point as measured in a direction perpendicular to a face of the die to which the TIM is coupled; the thin point is based on a predicted high-stress area of the die; and the thick point is based on a predicted low-stress area of the die.

Example 2 includes the microelectronic package of example 1, wherein the thick point is located at a central portion of the die.

Example 3 includes the microelectronic package of example 1, wherein the thin point is located at a periphery of the die.

Example 4 includes the microelectronic package of example 1, wherein the thick point of the IHS corresponds to a thin area of the TIM, and wherein the thin point of the IHS corresponds to a thick area of the TIM as measured in a direction perpendicular to the face of the die.

Example 5 includes the microelectronic package of example 4, wherein the TIM has a thickness of between 9 mils and 16 mils at the thick area of the TIM.

Example 6 includes the microelectronic package of example 4, wherein the TIM has a thickness of less than 8 mils at the thin area of the TIM.

Example 7 includes the microelectronic package of any of examples 1-6, wherein the feature has a footprint that is less than a footprint of the die as measured in a direction parallel to the face of the die.

Example 8 includes the microelectronic package of any of examples 1-6, wherein the TIM is a solder TIM (STIM).

Example 9 includes the microelectronic package of any of examples 1-6, wherein the TIM is a polymer TIM (PTIM).

Example 10 includes the microelectronic package of any of examples 1-6, wherein the feature has a curved non-uniform cross-sectional profile.

Example 11 includes the microelectronic package of any of examples 1-6, wherein the non-uniform cross-sectional profile of the feature includes a plurality of linear sections, and at least two of the plurality of linear sections are not parallel to one another.

Example 12 includes an IHS for a microelectronic package, wherein the IHS includes: a face that is to couple with a TIM of the microelectronic package, wherein the TIM is to be coupled with a face of a die; and a feature positioned on the face of the IHS, wherein: the feature is to couple with the TIM; a distance between a face of the feature and the face of the IHS is at least one mil; and a footprint of the feature is smaller than a footprint of the die as measured in a direction parallel to the face of the IHS.

Example 13 includes the IHS of example 12, wherein the feature is a pedestal that protrudes from the face of the IHS.

Example 14 includes the IHS of example 12, wherein the feature is a cavity that is recessed into the IHS.

Example 15 includes the IHS of any of examples 12-14, wherein the feature has a curved cross-sectional profile.

Example 16 includes the IHS of any of examples 12-14, wherein the feature has an angular cross-sectional profile with a plurality of linear portions, and at least two of the linear portions are not parallel to one another and are not perpendicular to one another.

Example 17 includes a method of forming a microelectronic package comprising: identifying a TIM, wherein the TIM is to transfer thermal energy from a die of the microelectronic package; and coupling the TIM to a face of an IHS, wherein the face of the IHS includes a feature with a non-uniform cross-sectional profile that has a footprint that is smaller than a footprint of the die.

Example 18 includes the method of example 17, wherein after the TIM is coupled with the IHS the TIM has a non-linear profile that includes a thick portion and a thin portion.

Example 19 includes the method of example 18, wherein the thick portion has a thickness of between 9 mils and 16 mils.

Example 20 includes the method of example 18, wherein the thin portion has a thickness of less than 8 mils.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. A microelectronic package comprising:
a die;
a thermal interface material (TIM) coupled with the die; and
an integrated heat spreader (IHS) coupled with the TIM, wherein:
the IHS has a feature with a non-uniform cross-sectional profile that includes a thin point and a thick point as measured in a direction perpendicular to a face of the die to which the TIM is coupled;
the thin point is based on a predicted high-stress area of the die; and
the thick point is based on a predicted low-stress area of the die.

2. The microelectronic package of claim 1, wherein the thick point is located at a central portion of the die.

3. The microelectronic package of claim 1, wherein the thin point is located at a periphery of the die.

4. The microelectronic package of claim 1, wherein the thick point of the IHS corresponds to a thin area of the TIM, and wherein the thin point of the IHS corresponds to a thick area of the TIM as measured in a direction perpendicular to the face of the die.

5. The microelectronic package of claim 4, wherein the TIM has a thickness of between 9 mils and 16 mils at the thick area of the TIM.

6. The microelectronic package of claim 4, wherein the TIM has a thickness of less than 8 mils at the thin area of the TIM.

7. The microelectronic package of claim 1, wherein the feature has a footprint that is less than a footprint of the die as measured in a direction parallel to the face of the die.

8. The microelectronic package of claim 1, wherein the TIM is a solder TIM (STIM).

9. The microelectronic package of claim 1, wherein the TIM is a polymer TIM (PTIM).

10. The microelectronic package of claim 1, wherein the feature has a curved non-uniform cross-sectional profile.

11. The microelectronic package of claim 1, wherein the non-uniform cross-sectional profile of the feature includes a plurality of linear sections, and at least two of the plurality of linear sections are not parallel to one another.

12. An integrated heat spreader (IHS) for a microelectronic package, wherein the IHS includes:
a face that is to couple with a thermal interface material (TIM) of the microelectronic package, wherein the TIM is to be coupled with a face of a die; and
a feature positioned on the face of the IHS, wherein:
the feature is to couple with the TIM;
a distance between a face of the feature and the face of the IHS is at least one mil; and
a footprint of the feature is smaller than a footprint of the die as measured in a direction parallel to the face of the IHS.

13. The IHS of claim 12, wherein the feature is a pedestal that protrudes from the face of the IHS.

14. The IHS of claim 12, wherein the feature is a cavity that is recessed into the IHS.

15. The IHS of claim 12, wherein the feature has a curved cross-sectional profile.

16. The IHS of claim 12, wherein the feature has an angular cross-sectional profile with a plurality of linear portions, and at least two of the linear portions are not parallel to one another and are not perpendicular to one another.

17. A method of forming a microelectronic package comprising:
identifying a thermal interface material (TIM), wherein the TIM is to transfer thermal energy from a die of the microelectronic package; and
coupling the TIM to a face of an integrated heat spreader (IHS), wherein the face of the IHS includes a feature with a non-uniform cross-sectional profile that has a footprint that is smaller than a footprint of the die.

18. The method of claim 17, wherein after the TIM is coupled with the IHS the TIM has a non-linear profile that includes a thick portion and a thin portion.

19. The method of claim 18, wherein the thick portion has a thickness of between 9 mils and 16 mils.

20. The method of claim 18, wherein the thin portion has a thickness of less than 8 mils.
